(19) United States
(12) Patent Application Publication
(10) Pub. No.: US 2025/0336778 A1
(43) Pub. Date: Oct. 30, 2025

(54) IC PACKAGE WITH CONNECTION PADS FOR DIE

(71) Applicant: TEXAS INSTRUMENTS INCORPORATED, DALLAS, TX (US)

(72) Inventors: KUAN-TING LIU, Taichung City (TW); BOB LEE, ZHONGHE DIST (TW)

(21) Appl. No.: 18/649,525

(22) Filed: Apr. 29, 2024

(51) Int. Cl. H01L 23/495; H01L 21/027; H01L 21/48; H01L 21/56; H01L 23/00; H01L 25/065

(52) U.S. Cl. CPC H01L 23/49548; H01L 21/0273; H01L 21/4821; H01L 21/565; H01L 23/4952; H01L 23/49586; H01L 24/11; H01L 24/16; H01L 24/81; H01L 25/0655; H01L 2224/11849; H01L 2224/16059; H01L 2224/16257; H01L 2224/81815; H01L 2924/182; H01L 2924/2075

(57) ABSTRACT

An IC (integrated circuit) package includes a first interconnect. The first interconnect includes a first surface comprising connection pads. The connection pads include cavity pillars on the first surface and the cavity pillars include a recess in the first surface with a pillar in a center region of a respective cavity pillar. The first interconnect includes a second surface opposing the first surface having connection pads for leads. The IC package includes a second interconnect with the leads mounted on the connection pads of the second surface of the first interconnect. The IC package also includes a die mounted with solder bumps on the connection pads of the first surface of the first interconnect. A portion of the solder bumps flow over the cavity pillars.

### TECHNICAL FIELD

This disclosure relates to IC (integrated circuit) packages that include an interconnect with connection pads for a die.

### BACKGROUND

ICs (integrated circuits) packages are the cornerstone of modern electronics, found in everything from computers and mobile devices to automobiles and industrial machinery. As the demand for smaller, faster and more energy-efficient devices continues to grow, the semiconductor industry is challenged to improve IC packaging technologies to meet these demands.

Some IC packages are fabricated using an interconnect (alternatively referred to as a leadframe) as a support structure, providing mechanical stability, electrical connectivity and heat dissipation for a semiconductor die. The interconnect includes a die pad for mounting the semiconductor die. One of the challenges in IC packaging is the formation of reliable solder joints between the die and the interconnect. Cracking of solder joints leads to failure of the IC package.

### SUMMARY

A first example relates to an IC (integrated circuit) package including a first interconnect. The first interconnect includes a first surface including connection pads. The connection pads include cavity pillars on the first surface and the cavity pillars include a recess in the first surface with a pillar in a center region of a respective cavity pillar. The first interconnect includes a second surface opposing the first surface having connection pads for leads. The IC package includes a second interconnect with the leads mounted on the connection pads of the second surface of the first interconnect. The IC package also includes a die mounted with solder bumps on the connection pads of the first surface of the first interconnect. A portion of the solder bumps flow over the cavity pillars.

A second example relates to a method for forming an IC package. The method includes forming connection pads that extend between a top surface and a bottom surface of an interconnect. The method also includes forming cavity pillars on a portion of the connection pads that are exposed on the top surface of the interconnect. The cavity pillars include a recess in the top surface of the interconnect with a pillar in a center region of a respective cavity pillar.

### BRIEF DESCRIPTION OF THE DRAWINGS

FIG. 1A illustrates an example of an IC package that includes a first interconnect with cavity pillars on connection pads.

FIG. 1B illustrates a zoomed-in view of a region of the IC package of FIG. 1A that includes a cavity pillar and solder to form a solder bump between a connection node of a die and the connection pad of the first interconnect.

FIG. 2A illustrates an IC package that includes a first interconnect with a first die and a second die mounted on a top surface of the first interconnect.

FIG. 2B illustrates the first interconnect of FIG. 2A with other components removed for clarity.

FIG. 2C illustrates a zoomed-in version of the region of the first interconnect of FIG. 2B.

FIG. 3 illustrates a simplified diagram of a solder bump formed with a copper cavity pillar.

FIG. 4A illustrates a heat map of an IC package during a temperature profile test.

FIG. 4B illustrates another heat map during the temperature profile test of the IC package of FIG. 4A where a mold compound of is removed.

FIG. 4C illustrates a strain distribution map during the temperature profile test for the IC package of FIGS. 4A and 4B.

FIG. 5 Illustrates a chart that plots a strain of the IC package of FIG. 4A-4C that includes cavity pillars as a function of time during the temperature profile test.

FIG. 6 illustrates a stress distribution chart for a region of an IC package with maximum strain depicted by a marker of FIG. 4C.

FIG. 7 illustrates a bar chart that compares a maximum sheer stress for a region of the IC package depicted by a marker of FIG. 4C.

FIGS. 8-15, 16A, 16B, 17A, 17B, 18A, 18B and 19-23 illustrate stages of a method for fabricating an IC package.

FIG. 24 illustrates a flowchart of an example method for forming an IC package.

FIG. 25 illustrates a flowchart of an example sub-method for forming cavity pillars on an interconnect for the IC package formed by the method of FIG. 24.

### DETAILED DESCRIPTION

This description relates to an IC package, and a method for fabricating the IC package that enhances the structural integrity and electrical performance of the IC package. The IC package includes of an interconnect (alternatively referred to as a routable leadframe) that has connection pads for a die. Cavity pillars, such as a recess (e.g., a cavity) with a pillar extruding from a center region of the recess are formed on these connection pads to facilitate robust solder joint formation, particularly beneficial in fine-pitch applications.

These cavity pillars are created on the surface of the interconnect where solder will be applied (the connection pads), and the cavity pillars are designed such that the recess and the cavity pillar form an anulus, and the pillar in the recess extends in a direction normal to the surface of the interconnect. The cavity pillars are formed using a process that includes depositing a photoresist layer, patterning the photoresist to form a rings of photoresist material and electroplating copper around the remaining photoresist to form the pillars of the cavity pillars. The remaining photoresist is removed to provide the recesses of the cavity pillars. In some examples, the cavity pillars have a ring shape.

The cavity pillars provide several advantages. The cavity pillars offer a high degree of precision in the placement of solder, which is helpful as the spacing between connections becomes increasingly narrow in modern IC designs. Additionally, the material chosen for the cavity pillars (e.g., copper) has favorable thermal and electrical properties, which contribute to the overall performance of the IC package.

Once the cavity pillars are formed, solder is applied to the cavity pillars in preparation for the reflow process. This solder application can be achieved through various techniques, including screen printing or other deposition methods. The solder is reflowed to create a mechanical and electrical bond between the die and the interconnect. In particular, the solder flows into the recesses of the cavity pillars and encases the pillars of the cavity pillars.

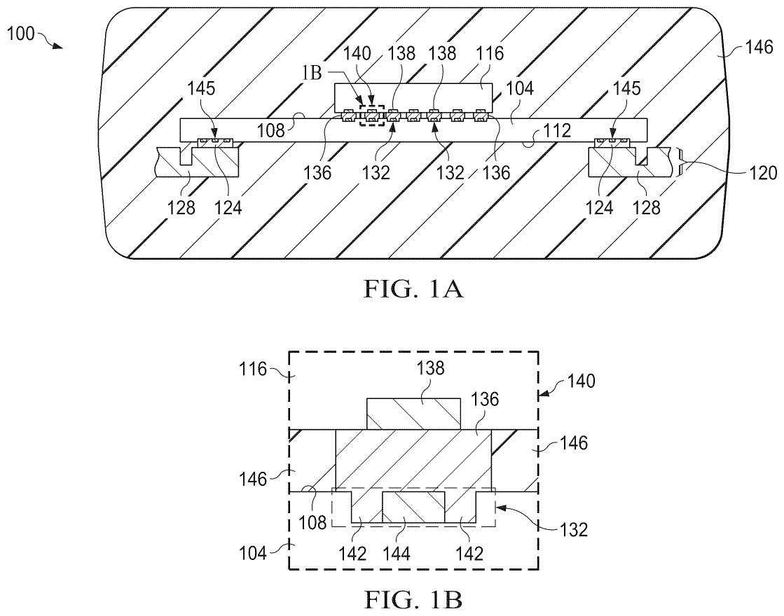

FIG. 1A illustrates an example of an IC package 100 that includes a first interconnect 104, that is alternatively referred to as a routable leadframe, or just a leadframe. The first interconnect 104 includes a top surface 108 (e.g., a first surface) and a bottom surface 112 (e.g., a second surface) that opposes the top surface 108. The first interconnect 104 includes connection pads (conductive traces) that extend between the top surface 108 and the bottom surface 112.

A die 116 (e.g., a semiconductor die) is mounted on the connection pads on the top surface 108 of the first interconnect 104. Additionally, the first interconnect 104 is mounted on a second interconnect 120 with solder bumps 124. The second interconnect 120 includes leads 128 for connecting the IC package 100 to external components, such as components on a PCB (printed circuit board). In some examples, the first interconnect 104 is coated with an isolation layer made of material such as ABF (Ajinomoto build-up film) to improve electrical isolation of the die 116. In some examples, the isolation layer (the ABF) is applied to the first interconnect 104 prior to mounting the die 116.

The top surface 108 of the first interconnect 104 includes cavity pillars 132 on the connection pads exposed at the top surface 108. The cavity pillars 132 include a recess (e.g., a cavity) with a pillar in a center region of the cavity pillar, such that the recess has a ring shape that circumscribes the pillar. The cavity pillars 132 have a circular cross section, and in some examples, the cavity pillars 132 have a diameter within a range of 4 micrometers (μm) to about 10 μm, such as about 5 μm to about 8 μm. The cavity pillars 132 are formed with copper in some examples. In other examples, the cavity pillars 132 are formed of a different material. The cavity pillars 132 facilitate the flow of solder 136 between connection nodes 138 (alternatively referred to as connection pads or contact pads) on the die 116 and the connection pads of the top surface 108 of the first interconnect 104.

FIG. 1B illustrates a zoomed-in view of a region 140 that includes a single cavity pillar 132 and solder 136 to form a solder bump between a connection node of the die 116 and the connection pad of the first interconnect 104. However, the other cavity pillars 132 illustrated in FIG. 1A have similar features. The cavity pillar 132 includes a recess 142 that is filled with the solder 136, and a pillar 144 in a center region of the cavity pillar 132. Accordingly, the recess 142 has a ring shape, and the recess 142 and the pillar 144 together form an anulus. Additionally, the solder 136 flows into the recess 142 and over a top and sides of the cavity pillar 132 to contact the connection node 138. Thus, the solder 136 forms a solder bump for the connection node 138. In some examples, the pillar 144 has a diameter of about 3 to about 5 micrometers (μm), and an annulus formed by the cavity pillar 132 has a diameter of about 4 to about 8 μm.

Referring back to FIG. 1A, in some examples, the cavity pillars 132 on the top surface 108 are considered a first set of cavity pillars, and the bottom surface 112 of the first interconnect 104 includes a second set of cavity pillars 145 that contact the solder bumps 124.

The first interconnect 104, the die 116 and a portion of the second interconnect 120 are encapsulated in a mold compound 146, such as plastic. Features of the IC package 100 have different CTEs (coefficients of thermal expansion). For instance, in some examples, the first interconnect 104 has a CTE of about 13 micrometers per degree Celsius (μm/° C.), the die 116 has a CTE of about 8 μm/° C. and the second interconnect 120 has a CTE of about 16 μm/° C. Thus, the largest difference in CTE is between the first interconnect 104 and the die 116. Additionally, there is a smaller difference in CTE between the first interconnect 104 and the second interconnect 120. In a conventional approach (where the first set of cavity pillars 132 and/or the second set of cavity pillars 145 are not included), these differences in CTE can lead to cracking of the solder 136 and/or the solder bumps 124. However, the first set of cavity pillars 132 and/or the second set of cavity pillars 145 provide an anchorage effect to improve the reliability of joints between the first interconnect 104 and the die 116 and/or between the first interconnect 104 and the second interconnect 120. Moreover, in the event that a crack in the solder 136 does occur, the cavity pillars 132 on the top surface 108 prevent spreading of the crack, thereby curtailing delamination of the die 116, and improving overall performance and reliability of the IC package 100. Also, the second set of cavity pillars 145 prevent the spread of cracks in the solder bumps 124 in a similar manner.

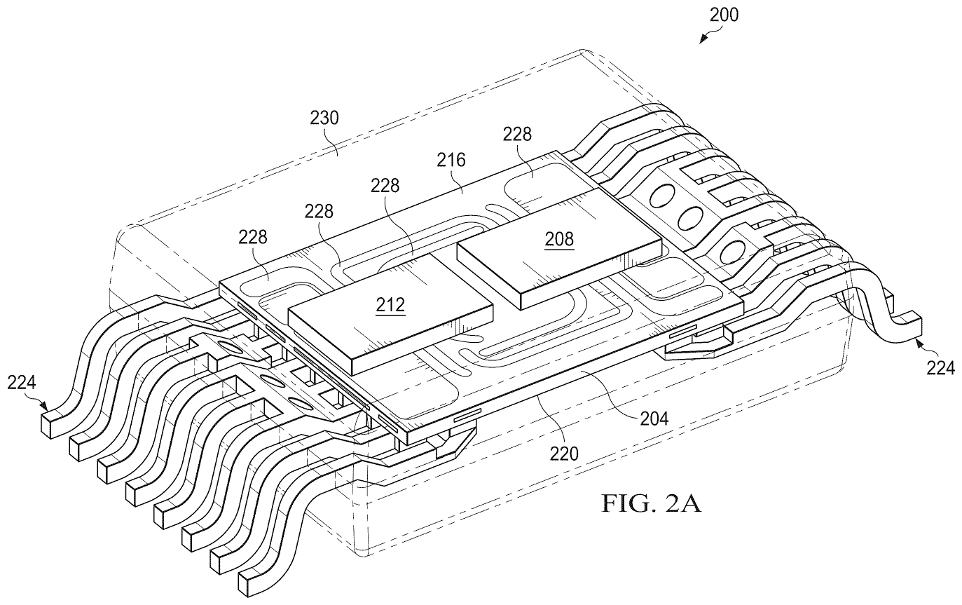

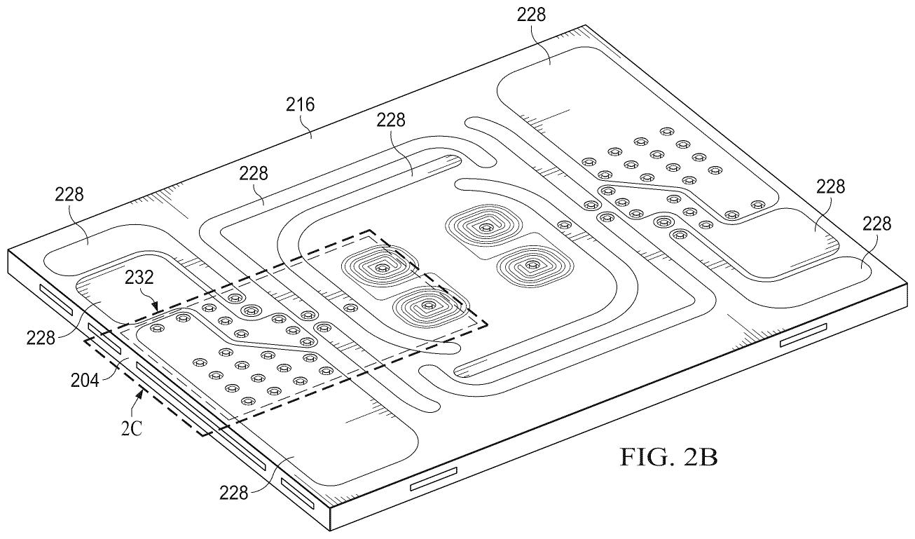

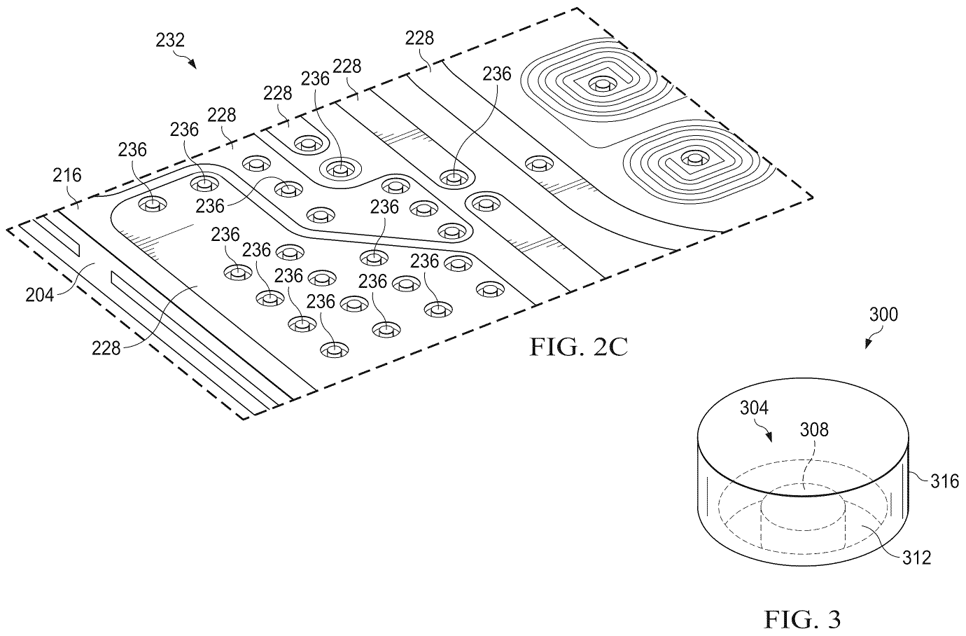

FIGS. 2A-2C depict components of an IC package 200. Moreover, FIGS. 2A-2C employ the same reference numbers to denote the same structures. The IC package 200 is employable to implement the IC package 100 of FIG. 1A.

More specifically, FIG. 2A illustrates the IC package 200 that includes a first interconnect 204 with a first die 208 and a second die 212 mounted on a top surface 216 (e.g., a first surface) of the first interconnect 204. The first interconnect 204 is alternatively referred to as a routable leadframe. A bottom surface (e.g., a second surface) of the first interconnect 204 is mounted on a second interconnect 220 that includes leads 224. The leads 224 are trimmed and formed to enable connections to external components, such as components mounted on a PCB.

The first interconnect 204 includes connection pads 228 on the top surface 216. Some of the connection pads 228 extend between the top surface 216 and the bottom surface. Accordingly, the first die 208 and the second die 212 are coupled to the leads 224. Additionally, some of the connection pads 228 enable communication between the first die 208 and the second die 212. A mold compound 230 (e.g., plastic) encapsulates the first interconnect 204, the first die 208, the second die 212 and a portion of the second interconnect 220, such as a portion of the leads 224.

FIG. 2B illustrates the first interconnect 204 with other components removed for clarity. The first interconnect 204 includes the connection pads 228 on the top surface 216. As noted, some of the connection pads 228 extend between the top surface 216 and the bottom surface. The first interconnect 204 is coated with ABF (Ajinomoto build-up film) in some examples. This ABF provides an electrical isolation layer disposed between the first interconnect 204 and a die mounted thereon (the first die 208 and/or the second die 212 of FIG. 1A). In some situations, the ABF is applied to the first interconnect 204 prior to mounting such dies. Also, FIG. 2B includes a region 232, and FIG. 2C illustrates a zoomed-in version of the region 232.

As illustrated in FIG. 2C, the connection pads 228 include multiple cavity pillars 236 (the same as the cavity pillars 132 of FIGS. 1A and 1B), only some of which are labeled. The cavity pillars 236 are formed of the same material as the connection pads 228, namely a conductive material, such as copper. The cavity pillars 236 have a ring-shaped recess and a pillar in a center region of the cavity pillar. Thus, the ring-shaped recess and the pillar of the cavity pillars 236 form annuli. Moreover, the cavity pillars 236 have a cylindrical shape with a circular cross-section. In some examples, the pillars of the cavity pillars 236 have a diameter of about 3 μm to about 5 μm, and the annuli formed by the cavity pillars 236 have a diameter of about 4 μm to about 8 μm.

The cavity pillars 236 provide an anchorage effect for attaching the first die 208 and the second die 212 to the first interconnect 204. More specifically, solder between the first die 208 and the first interconnect 204 and solder between the second die 212 and the first interconnect 204 encases the cavity pillars 236. Thus, the cavity pillars 236 provide mechanical resistance to cracking, and distribute stress and strain caused by thermal expansion of the first die 208 and the second die 212 and the first interconnect 204.

FIG. 3 illustrates a simplified diagram of a solder bump 300 formed with a cavity pillar 304, such as one of the cavity pillars 236 of FIG. 2C. The cavity pillar 304 includes a pillar 308 (formed of copper or other conductive material) in a center region of the cavity pillar 304. The pillar 308 extends in a direction normal to a surface of an interconnect, such as the top surface 216 of FIGS. 2A-2C. The pillar 308 is circumscribed by a recess 312 that is ring-shaped. Thus, the recess 312 and the pillar 308 form an annulus. In some examples, the pillar 308 has a diameter of about 3 μm to about 5 μm and the annulus has a diameter of about 4 to about 8 μm. Solder 316 encases the copper cavity pillar 304, flowing into the recess 312, and over a top and sides of the pillar 308.

Referring back to FIG. 2A, during operation, the cavity pillars 236 curtail cracking caused by thermal expansion. Additionally, should a crack in solder occur, the cavity pillars 236 prevent and/or impede such a crack from expanding, thereby reducing a chance of delamination of the first die 208 and the second die 212 from the first interconnect 204.

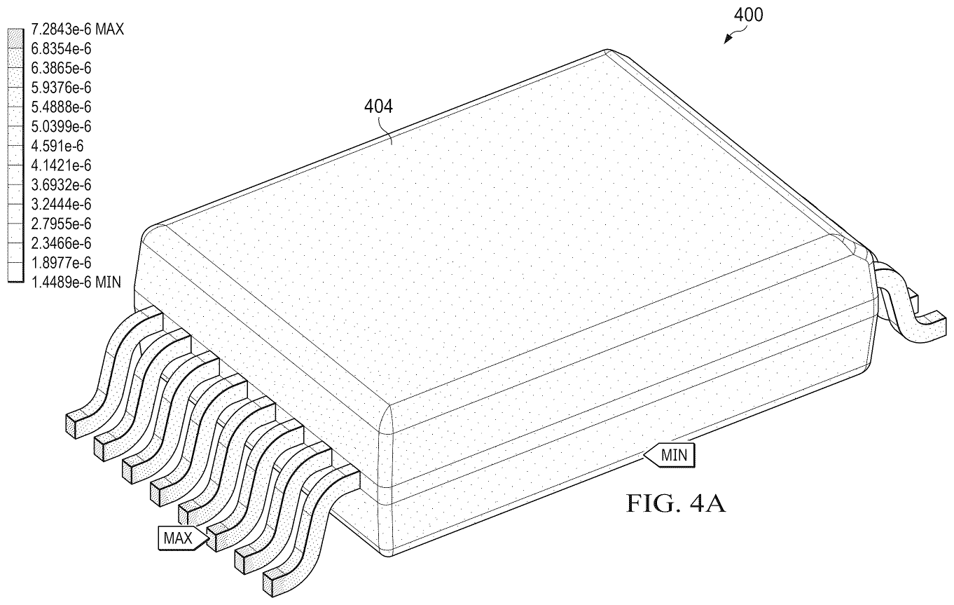

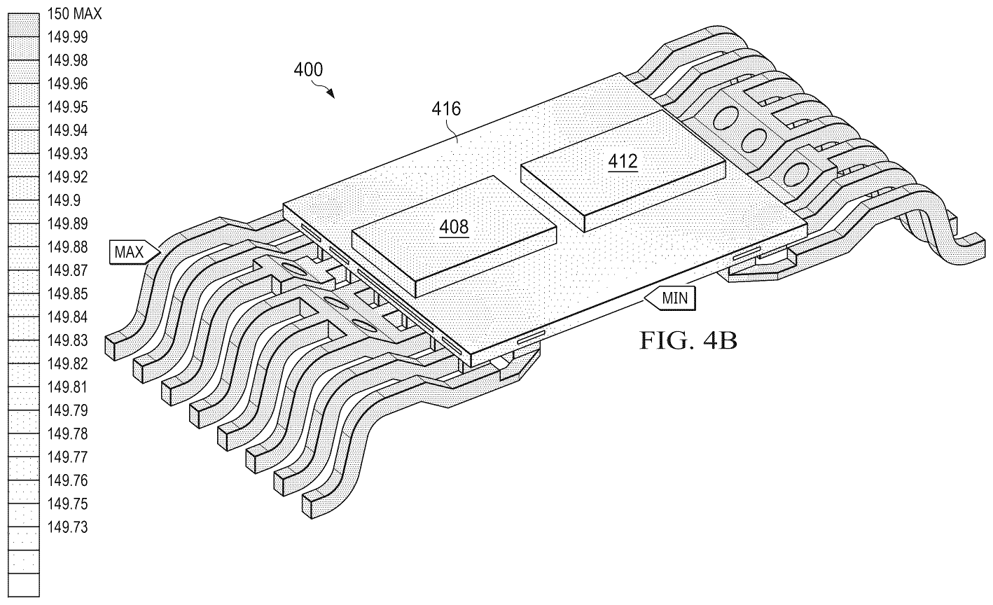

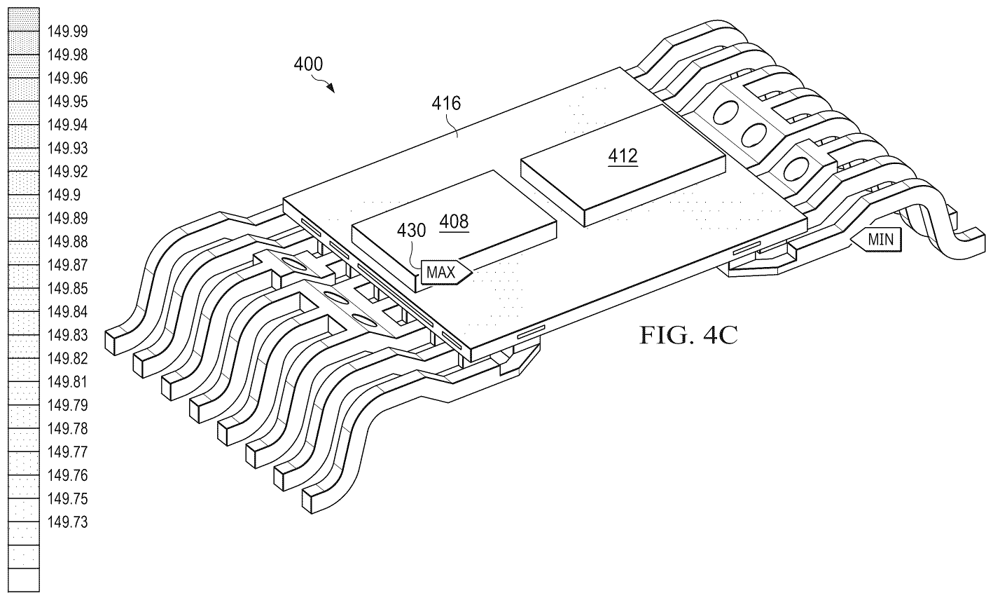

FIGS. 4A-4B illustrate heat maps of an IC package 400 during a thermal profile test. The IC package 400 includes cavity pillars, such as the cavity pillars 236 of FIG. 2A-2C. During the thermal profile test, a temperature of the IC package 400 is raised from about −55° C. to about 150° C. and lowered back to −55° C. over a time of about 800 seconds. This temperature cycle is executed twice, and the heat of the IC package 400 is recorded during the temperature profile test. In the diagrams illustrated in FIG. 4A-4C, it is presumed that the heat shown is for a peak temperature (e.g., about 150° C.) of the temperature profile test.

FIG. 4A illustrates the IC package 400 wherein a mold compound 404 is included. FIG. 4B illustrates the IC package 400 where the mold compound 404 is removed, to show the heat map for a first die 408, a second die 412 and a first interconnect 416.

FIG. 4C illustrates a strain distribution map for the IC package 400. FIG. 4C employs the same reference numbers as FIGS. 4A and 4B to denote the same structure. Additionally, the strain distribution map includes a marker 430 that denotes a point with a greatest strain, caused by a difference in thermal expansion of the first die 408 and the first interconnect 416.

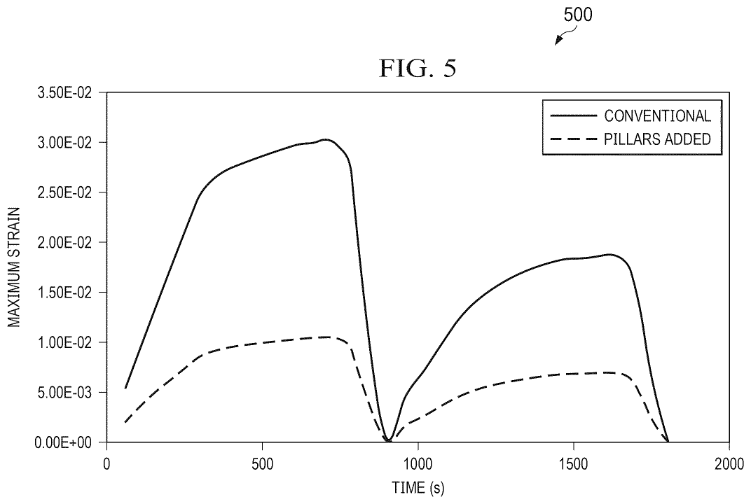

FIG. 5 Illustrates a chart 500 that plots a strain of the IC package 400 of FIG. 4A-4C that includes cavity pillars (e.g., the cavity pillars 236 of FIG. 2A-2C) as a function of time during the temperature profile test. The chart 500 also plots a strain of a conventional IC package that omits cavity pillars. As illustrated, including the cavity pillars reduces the maximum strain from about 3.00E-02 to about 1.1 E-02 during the first temperature cycle of the temperature profile test. Additionally, including the cavity pillars reduces the maximum strain from about 1.80E-02 to about 0.75E-02 during the second temperature cycle of the temperature profile test.

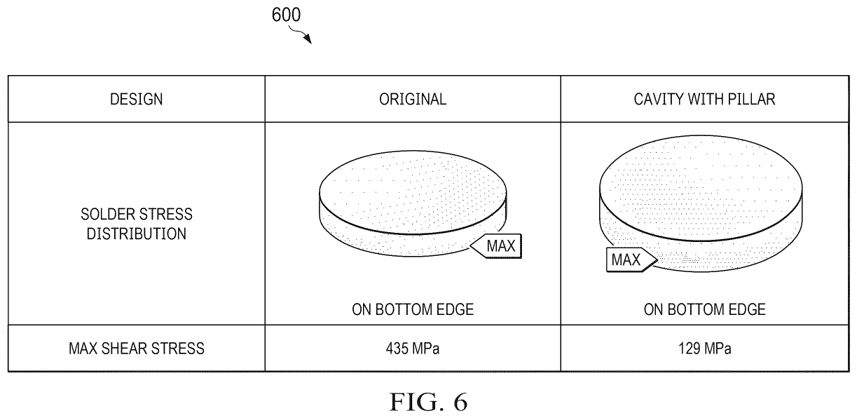

FIG. 6 illustrates a stress distribution chart 600 for the region of the IC package 400 with maximum strain depicted by the marker 430 of FIG. 4C. The chart 600 includes a stress distribution for a conventional approach where the cavity pillars are omitted, and a stress distribution where the cavity pillars are included, such as the IC package 400 of FIGS. 4A-4C. As illustrated, including the cavity pillars reduces a maximum shear stress from about 435 mega Pascals (MPa) to about 129 MPa.

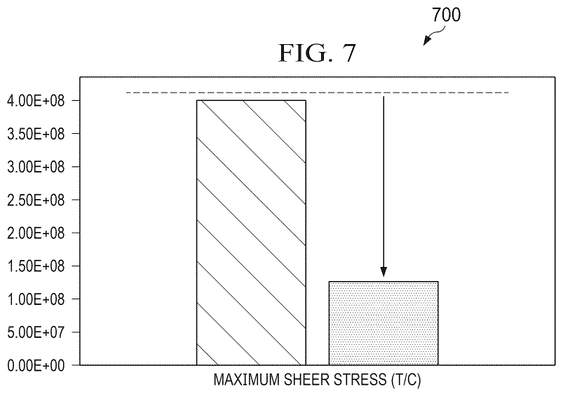

FIG. 7 illustrates a bar chart 700 that compares a maximum sheer stress for a region of the IC package 400 depicted by the marker 430 of FIG. 4C. The chart 700 includes a maximum shear stress distribution for a conventional approach where the cavity pillars are omitted, and a maximum sheer stress where the cavity pillars are included, such as the IC package 400 of FIGS. 4A-4C. As illustrated, including the cavity pillars reduces a maximum shear stress by about 70%, consistent with the stress distribution chart 600 of FIG. 6.

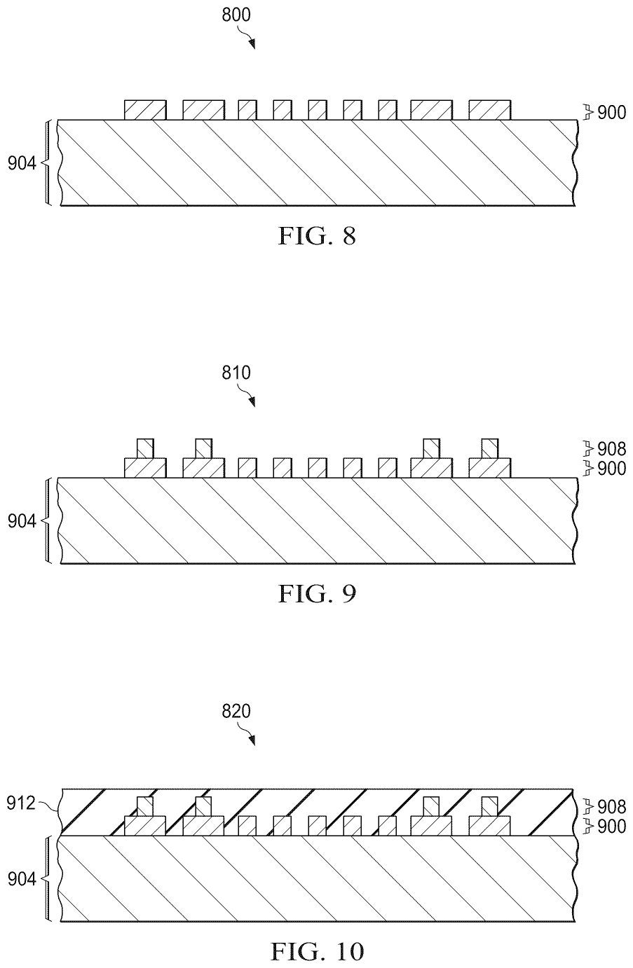

FIGS. 8-15, 16A and 16B, 17A and 17B, 18A and 18B and 19-23 illustrate stages of a method for fabricating an IC package such as the IC package 100 of FIG. 1A and/or the IC package 200 of FIG. 2A. The method of FIGS. 8-15, 16A and 16B, 17A and 17B, 18A and 18B and 19-23 illustrate how cavity pillars are added to an interconnect (e.g., a routable leadframe).

As illustrated in FIG. 8, at 800, in a first stage, a first metal layer pattern 900 is plated on a metal carrier 904. As illustrated in FIG. 9, in a second stage, at 810, pillars 908 (e.g., copper pillars or pillars formed of other metal) are plated on the first metal layer pattern 900. As illustrated in FIG. 10, at 820, in a third stage, a first dielectric layer 912 is applied in a compressed molding operation to the pillars 908 and to the first metal layer pattern 900. As illustrated in FIG. 11, in a fourth stage, at 825, a portion of the first dielectric layer 912 is removed in a grinding operation, such that regions of the pillars 908 are exposed.

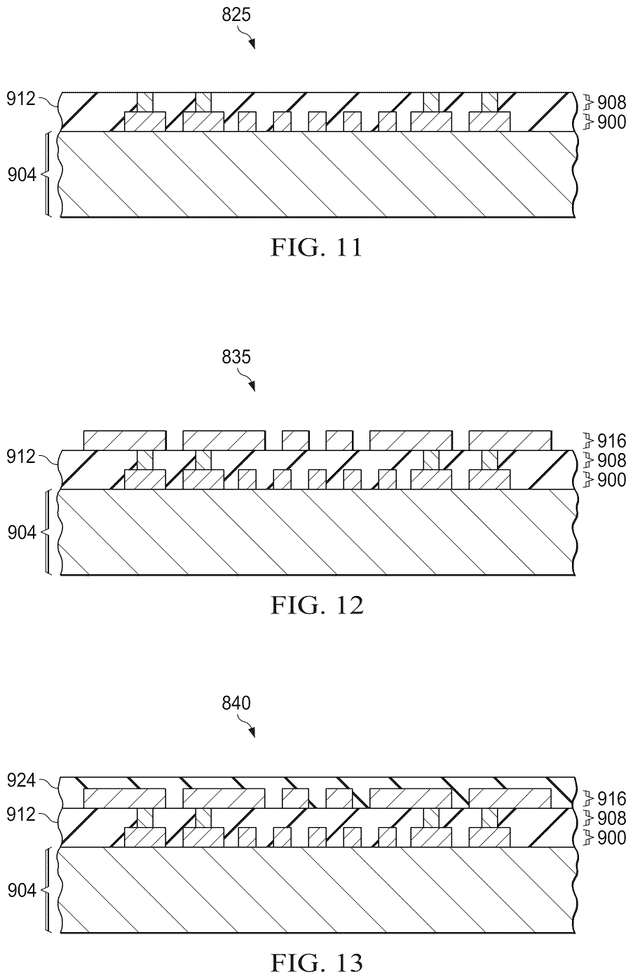

As illustrated in FIG. 12, in a fifth stage, at 835, a second metal layer pattern 916 is plated on the first dielectric layer 912. As illustrated in FIG. 13, in a sixth stage, at 840 a second dielectric layer 924 is applied in a compressed molding operation to the cavity pillars 908 and to the second metal layer pattern 916. As illustrated in FIG. 14, in a seventh stage, at 845, a portion of the second dielectric layer 924 is removed in a grinding operation, such that regions of the second metal layer pattern 916 (connection pads) are exposed.

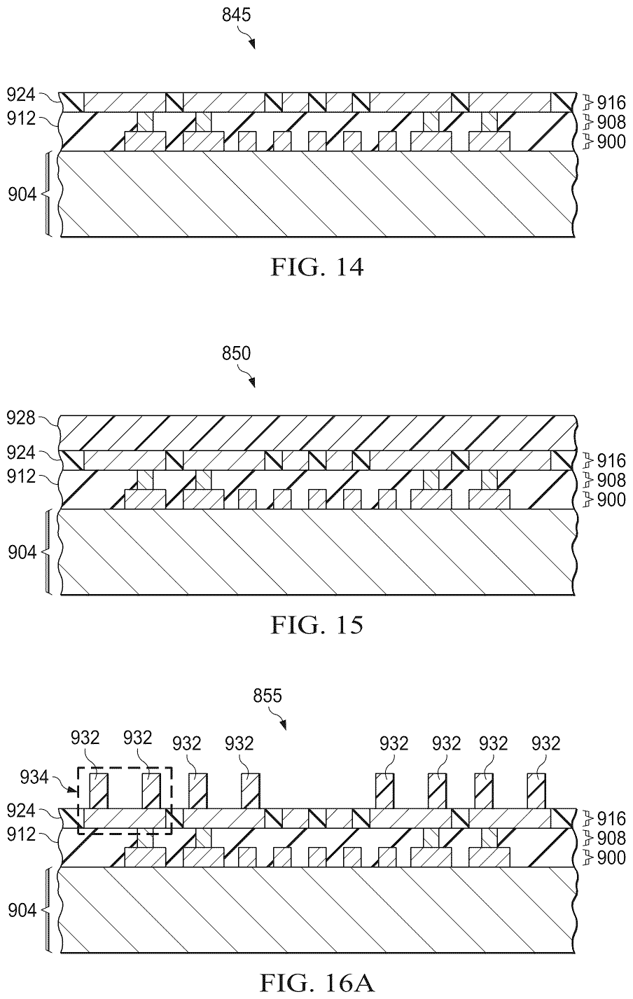

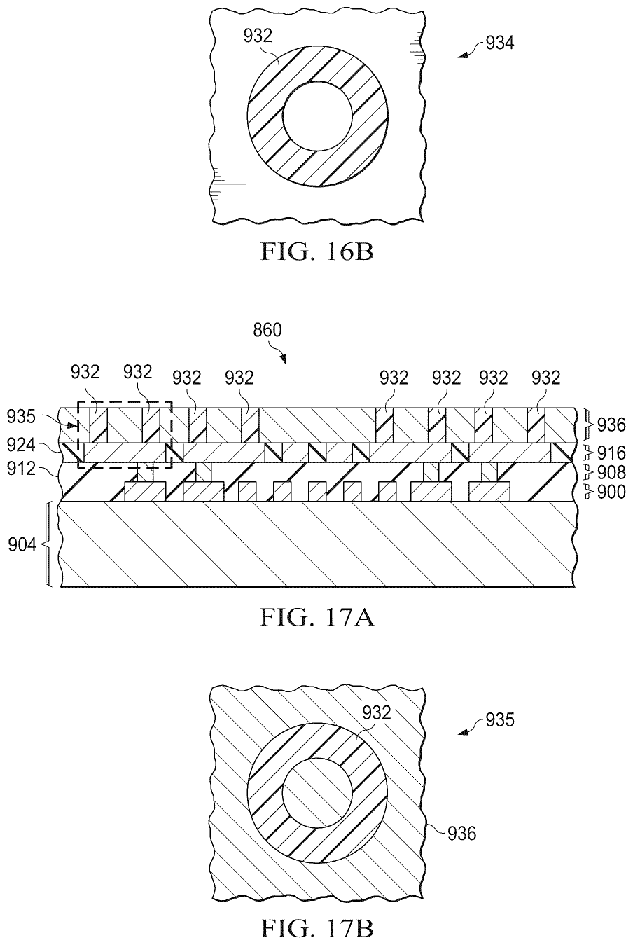

As illustrated in FIG. 15, in an eighth stage, at 850, a layer of dry film 928 (e.g., a photoresist layer) is overlaid on the second dielectric layer 924 and the second metal layer pattern 916. As illustrated in FIG. 16A, in a ninth stage at 855, the layer of dry film 928 is etched to provide rings 932 of the dry film 928 (e.g., rings of photoresist). FIG. 16B illustrates an overhead view of a region 934 of FIG. 16A. As illustrated in FIG. 16B, the remaining dry film 928 forms a ring 932 of dry film 928.

As illustrated in FIG. 17A, in a tenth stage, at 860, a conductive material 936, such as copper is plated around the rings 932 of the remaining dry film 928. FIG. 17B illustrates an overhead view of a region 935 of FIG. 17A. As illustrated in FIG. 17B, the ring 932 of the dry film 928 is circumscribed by the conductive material 936.

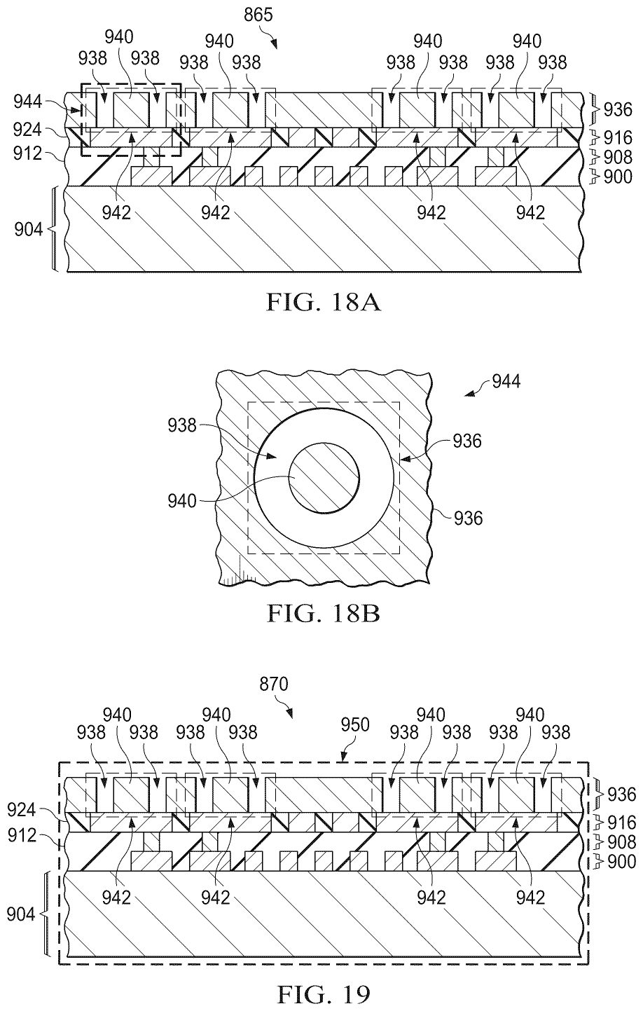

As illustrated in FIG. 18A, in an eleventh stage at 865, the remaining dry film 928 is removed (stated differently, the remaining photoresist layer is removed), such that the rings 932 are removed to provide recesses 938 (e.g., voids) that circumscribe pillars 940, such that cavity pillars 942 are provided. FIG. 18B illustrates an overhead view of a region 944 of FIG. 18A that includes a single cavity pillar 942. As illustrated in FIG. 18A, the cavity pillar 942 includes a recess 938 that circumscribes a pillar 940, such that the recess 938 and the pillar 940 form an annulus.

As illustrated in FIG. 19, in a twelfth stage at 870, the metal carrier 904 is removed in a de-carrier operation to provide a first interconnect 950 (e.g., a routable leadframe). The first interconnect 950 may also include cavity pillars (corresponding to the second set of cavity pillars 145 in FIG. 1A) on a bottom surface of the first interconnect 950 (corresponding to the bottom surface 112 in FIG. 1A on the first interconnect 104 using the same operations to form the first set of cavity pillars 132 for the top surface 108 of the first interconnect 104). The de-carrier operation executed at 870 exposes a region of the first metal layer pattern 900 to enable the second metal layer pattern 916 (connection pads) to be conductively coupled to connection pads formed on the first metal layer pattern 900.

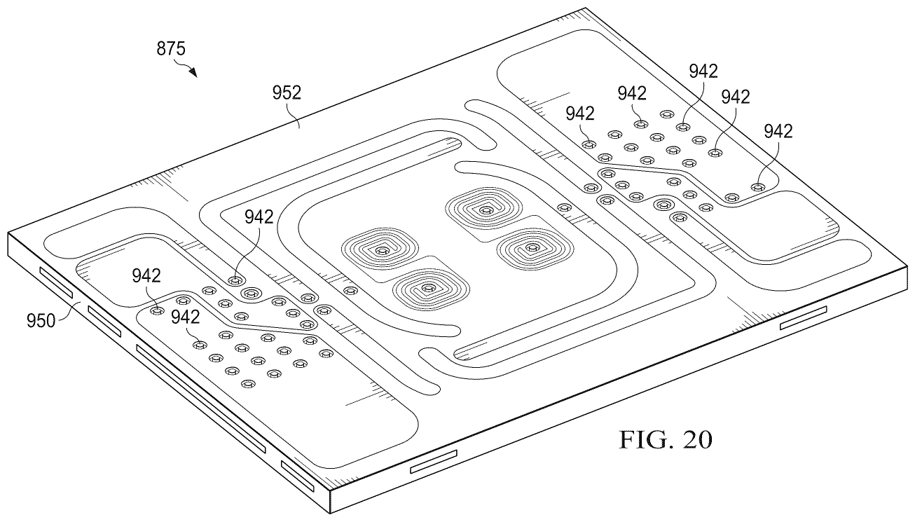

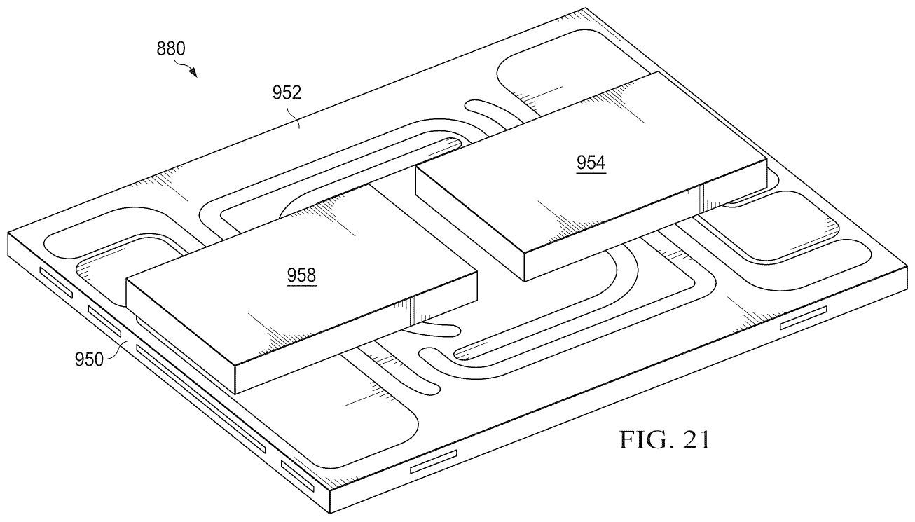

As illustrated in FIG. 20, in a thirteenth stage at 875, the first interconnect 950 is provided (e.g., in an isometric view). The first interconnect 950 is employable to implement the first interconnect 104 of FIG. 1A and/or the first interconnect 204 of FIGS. 2A-2B. Thus, the first interconnect 950 includes the cavity pillars 942 (too small for viewing in FIG. 20) on connection pads that are on a top surface 952 (e.g., a first surface) of the first interconnect 950. As illustrated in FIG. 21, in a fourteenth stage at 880, a first die 954 and a second die 958 are mounted on the top surface 952 of the first interconnect 950 using a flip-chip technique with a solder reflow operation. The solder encases the cavity pillars formed on the connection pads.

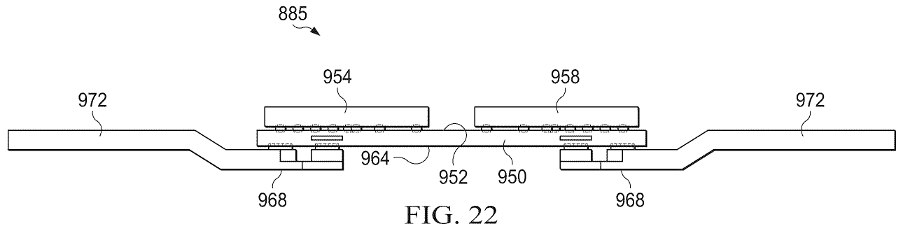

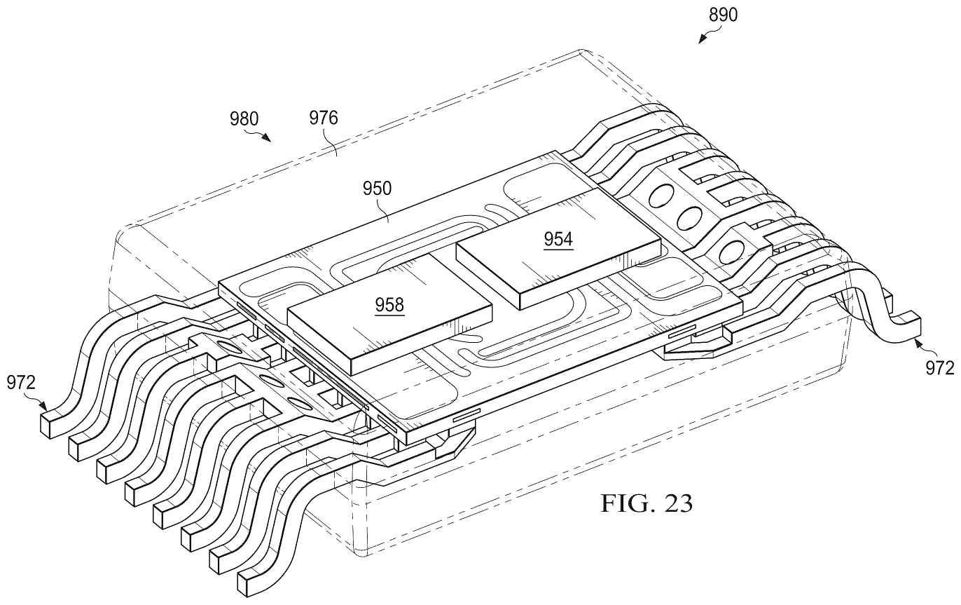

As illustrated in FIG. 22, in a fifteenth stage at 885, a bottom surface 964 of the first interconnect 950 is mounted on a second interconnect 968 that includes cavity pillars (corresponding to the second set of cavity pillars 145 in FIG. 1A) on the bottom surface of the first interconnect 950 to respective leads 972 with a solder reflow operation. The solder flows into the cavities surrounding the cavity pillars and encases the cavity pillars formed on the connection pads. Optionally, forming cavity pillars on the metal layer contacts on the bottom surface of the first interconnect 950 may be omitted with solder paste or solder balls being formed on the leads 972 or the metal contacts on the bottom surface of the first interconnect 950 after which a reflow operation will use the solder to make conductive connections between respective ones of the metal contacts on the bottom surface of the first interconnect 950 and the leads 972. As illustrated in FIG. 23, in a sixteenth stage at 890, the first interconnect 950, the first die 954, the second die 958 and a portion of the second interconnect 968 is encapsulated in a mold compound 976 through a mold flow operation. Additionally, at 890, the leads 972 are trimmed and formed to provide an IC package 980.

As illustrated in FIGS. 8-15, 16A and 16B, 17A and 17B, 18A and 18B and 19-23, by implementing the method, the cavity pillars 942 are formed with few operations, namely the operations at 850 of FIG. 15, 855 of FIG. 16A, 860 of FIG. 17A and at 865 of FIG. 18A. Thus, the benefits of the cavity pillars 942 (reduced stress and strain during temperature cycles) is achieved with adding relatively few processing operations to form the IC package 980.

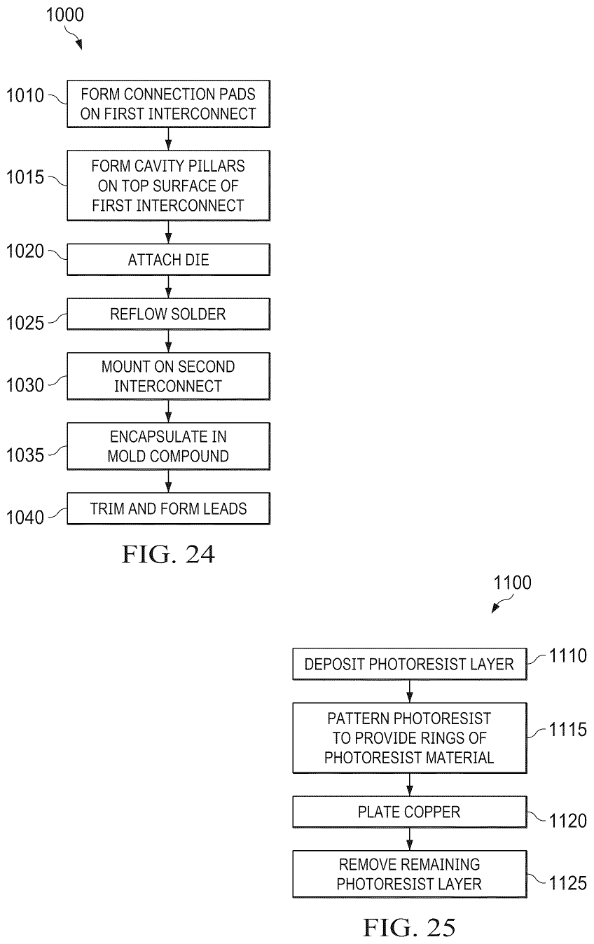

FIG. 24 illustrates a flowchart of an example method 1000 for forming an IC package (e.g., the IC package 100 of FIG. 1A and/or the IC package 200 of FIG. 2A). At block 1010, connection pads that extend between a top surface and a bottom surface of a first interconnect (e.g., the first interconnect 104 of FIG. 1A) are formed.

At block 1015, cavity pillars (e.g. the cavity pillars 132 of FIG. 1A) are formed on a portion of the connection pads that are exposed on the top surface of the first interconnect. The pillars include a recess and a pillar in a center region of the cavity pillar. The pillars of the cavity pillars are formed of a conductive material, such as copper. The cavity pillars extend in a directional normal to the top surface of the interconnect. FIG. 25 illustrates a flowchart of an example sub-method 1100 for forming the cavity pillars, as describe in block 1015 of FIG. 24. At block 1110, a photoresist layer (e.g., the dry film 928 of FIG. 15) is deposited over the top surface of the first interconnect. At block 1115, the photoresist layer patterned such that photoresist material cover portions of the connection pads where recesses of the cavity pillars are to be formed. Stated differently, the portions of the photoresist layer that form do not form the recess are removed, such that rings of the photoresist material (e.g., the rings 932 of FIGS. 16A and 16B) remain. At block 1120, copper (or other conductive material) is plated (e.g., electroplated) onto exposed portions of the connection pads. At block 1125, the remaining portions of the photoresist layer (the rings of photoresist material) is removed to form the cavity pillars.

Referring back to FIG. 24, at block 1020, a die is attached to the top surface of the first interconnect such that connection nodes of the die overlay the connection pads of the top surface of the interconnect. At block 1025, solder is reflowed onto the cavity pillars to form solder bumps for connecting the connection nodes of the die to the connection pads of the first interconnect. Thus, in block 1025, solder flows into recesses of the cavity pillars on the connection pads and encases the pillars of the cavity pillars.

At block 1030, a bottom surface of the first interconnect is mounted on a second interconnect (e.g., the second interconnect 120 of FIG. 1A) that includes leads (e.g., the leads 128 of FIG. 1A). At block 1035, the die, the first interconnect and a portion of the second interconnect is encapsulated in a mold compound. At block 1040, the leads are trimmed and formed to provide the IC package.

In this description, unless otherwise stated, “about,” preceding a parameter means being within +/−10 percent of that parameter. Modifications are possible in the described embodiments, and other embodiments are possible, within the scope of the claims.

What is claimed is:

1. An IC (integrated circuit) package comprising:
a first interconnect comprising:
a first surface comprising connection pads, wherein the connection pads include cavity pillars on the first surface and the cavity pillars comprise a recess in the first surface with a pillar in a center region of a respective cavity pillar; and
a second surface opposing the first surface having connection pads for leads;
a second interconnect comprising the leads mounted on the connection pads of the second surface of the first interconnect; and
a die mounted with solder bumps on the connection pads of the first surface of the first interconnect, wherein a portion of the solder bumps flow over the cavity pillars.

2. The IC package of claim 1, wherein the connection pads and cavity pillars of the first interconnect are formed with copper.

3. The IC package of claim 2, wherein the solder bumps have a first coefficient of thermal expansion and the copper has a second coefficient of thermal expansion that is different than the first coefficient of thermal expansion.

4. The IC package of claim 2, wherein the portion of the solder bumps encase the pillars of the cavity pillars and fill the recesses of the cavity pillars.

5. The IC package of claim 1, wherein the pillars of the cavity pillars have a circular cross section, and the recesses of the cavity pillars are ring-shaped.

6. The IC package of claim 5, wherein the recesses of the cavity pillars form an annulus about a respective cavity pillar.

7. The IC package of claim 6, wherein the pillars of the cavity pillars have a diameter of about 3 to about 5 micrometers.

8. The IC package of claim 7, wherein annuli formed by the recesses of the cavity pillars have a diameter of about 4 to about 8 micrometers.

9. The IC package of claim 1 further comprising an layer made of ABF (Ajinomoto build-up film) disposed on the first interconnect to provide electrical isolation for the die.

10. The IC package of claim 1, wherein each conductive pad of the connection pads includes multiple cavity pillars.

11. The IC package of claim 1, wherein contact pads on the die oppose the connection pads of the first interconnect.

12. The IC package of claim 1, wherein the cavity pillars are a first set of cavity pillars and the IC package further comprises a second set of cavity pillars on the connection pads of the second surface of the first interconnect.

13. A method for forming an IC (integrated circuit) package, the method comprising:
forming connection pads that extend between a top surface and a bottom surface of an interconnect; and
forming cavity pillars on a portion of the connection pads that are exposed on the top surface of the interconnect, wherein the cavity pillars comprise a recess in the top surface of the interconnect with a pillar in a center region of a respective cavity pillar.

14. The method of claim 13, wherein forming the cavity pillars further comprises:
depositing a photoresist layer over the top surface of the interconnect;
patterning the photoresist layer such that photoresist material covers portions of the connection pads where recesses of the cavity pillars are to be formed;
electroplating copper onto exposed portions of the connection pads; and
removing the photoresist layer to form the cavity pillars.

15. The method of claim 14, wherein the pillars of the cavity pillars have a circular cross section, and the recesses of the cavity pillars are ring-shaped.

16. The method of claim 14, further comprising:
attaching a die on the top surface of the interconnect such that connection nodes of the die overlay the connection pads on the top surface of the interconnect; and
reflowing solder onto the cavity pillars to form solder bumps for connecting die pads of the die to the connection pads of the interconnect.

17. The method of claim 16, further comprising applying ABF (Ajinomoto build-up film) to the interconnect prior to the attaching to increase electrical isolation.

18. The method of claim 16, wherein the portion of the solder bumps encase the pillars of the cavity pillars and fill the recesses of the cavity pillars.

19. The method of claim 16, wherein the interconnect is a first interconnect, the method further comprising mounting the first interconnect on a second interconnect that includes leads, wherein connection pads on the bottom surface of the first interconnect are soldered to the leads.

20. The method of claim 19, further comprising encapsulating the die, the first interconnect and a portion of the leads of the second interconnect in a mold compound.
